(19) United States
(12) Patent Application Publication
(10) Pub. No.: US 2026/0314016 A1
(43) Pub. Date: Oct. 8, 2026

(54) NITRIDE SEMICONDUCTOR DEVICE

(71) Applicant: ROHM CO., LTD., Kyoto (JP)

(72) Inventor: Hirotaka OTAKE, Kyoto (JP)

(73) Assignee: ROHM CO., LTD., Kyoto (JP)

(21) Appl. No.: 19/629,349

(22) Filed: Mar. 26, 2026

(30) Foreign Application Priority Data
Apr. 2, 2025 (JP) 2025-061279

(51) Int. Cl. H10D 64/00; H10D 30/01; H10D 30/47; H10D 62/10; H10D 64/23

(52) U.S. Cl. CPC H10D 64/111; H10D 30/015; H10D 30/475; H10D 62/102; H10D 62/124; H10D 64/251

(57) ABSTRACT

A nitride semiconductor device includes an electron transport layer, an electron supply layer, a gate layer including an acceptor impurity, a gate electrode over the gate layer, a passivation layer, a source electrode and a drain electrode. The source electrode includes a field plate section that covers the gate layer and the gate electrode. The field plate section includes a field plate end section that is positioned between the gate layer and the drain electrode. The electron supply layer includes a first recess that is formed in the top surface of the electron supply layer, and that overlaps the gate layer in a plan view, and a second recess that is formed in the top surface of the electron supply layer, and that overlaps the field plate end section in a plan view.

### CROSS REFERENCE TO RELATED APPLICATION

This application is based upon and claims the benefit of priority of the prior Japanese Patent Application No. 2025-061279, filed on Apr. 2, 2025, the entire contents of which are incorporated herein by reference.

### TECHNICAL FIELD

The present disclosure relates to a nitride semiconductor device.

### BACKGROUND ART

Currently, high electron mobility transistors (HEMT) using III-nitride semiconductors (sometimes referred to below simply as “nitride semiconductors”) such as gallium nitride (GaN) have increasingly been commercialized. HEMTs use, as a conductive path (channel), a 2-dimensional electron gas (2DEG) formed in the vicinity of a semiconductor heterojunction interface between an electron transport layer and an electron supply layer (e.g., see Japanese Patent Application Laid-Open Publication No. 2017-73506). Power devices using HEMTs are renowned for having a low ON resistance and being capable of high-speed/high-frequency operation compared to the typical silicon (Si) power devices.

### SUMMARY OF THE INVENTION

In HEMTs, if the thickness of the electron supply layer is increased in order to improve the gate withstand voltage, this can result in a decrease in the gate threshold as well as a reduction in drain-source withstand voltage, and thus, there can be a trade-off between improved gate withstand voltage and reduced gate threshold and drain-source withstand voltage.

A nitride semiconductor device according to an aspect of the present disclosure includes: an electron transport layer; an electron supply layer that is positioned over the electron transport layer and has a bandgap greater than the electron transport layer; a gate layer positioned over a portion of the electron supply layer, and including an acceptor impurity; a gate electrode positioned over a portion of the gate layer; a passivation layer that covers the electron supply layer, the gate layer, and the gate electrode, and that includes a source opening and a drain opening; a source electrode in contact with the electron supply layer via the source opening; and a drain electrode in contact with the electron supply layer via the drain opening. The source electrode includes a field plate section that covers the gate layer and the gate electrode, and the field plate section includes a field plate end section that is positioned between the gate layer and the drain electrode. The electron supply layer includes: a first recess that is formed in a top surface of the electron supply layer, and that overlaps the gate layer in a plan view; and a second recess that is formed in the top surface of the electron supply layer, and that overlaps the field plate end section in a plan view.

### BRIEF DESCRIPTION OF THE DRAWINGS

FIG. 1 is a schematic cross-sectional view (cross-sectional view along line F1-F1 of FIG. 3) of an exemplary nitride semiconductor device according to Embodiment 1.

FIG. 2 is a partial expanded cross-sectional view of the nitride semiconductor device shown in FIG. 1.

FIG. 3 is a schematic plan view of the nitride semiconductor device shown in FIG. 1.

FIG. 4 is a schematic cross-sectional view showing an exemplary manufacturing step for the nitride semiconductor device shown in FIG. 1.

FIG. 5 is a schematic cross-sectional view of an exemplary manufacturing step following the manufacturing step of FIG. 4.

FIG. 6 is a schematic cross-sectional view of an exemplary manufacturing step following the manufacturing step of FIG. 5.

FIG. 7 is a schematic cross-sectional view of an exemplary manufacturing step following the manufacturing step of FIG. 6.

FIG. 8 is a schematic cross-sectional view of an exemplary manufacturing step following the manufacturing step of FIG. 7.

FIG. 9 is a schematic cross-sectional view of an exemplary manufacturing step following the manufacturing step of FIG. 8.

FIG. 10 is a schematic cross-sectional view of an exemplary manufacturing step following the manufacturing step of FIG. 9.

FIG. 11 is a schematic cross-sectional view of an exemplary manufacturing step following the manufacturing step of FIG. 10.

FIG. 12 is a schematic cross-sectional view of an exemplary manufacturing step following the manufacturing step of FIG. 11.

FIG. 13 is a schematic cross-sectional view of an exemplary manufacturing step following the manufacturing step of FIG. 12.

FIG. 14 is a schematic cross-sectional view of an exemplary manufacturing step following the manufacturing step of FIG. 13.

FIG. 15 is a schematic cross-sectional view of an exemplary manufacturing step following the manufacturing step of FIG. 14.

FIG. 16 is a schematic cross-sectional view of an exemplary manufacturing step following the manufacturing step of FIG. 15.

FIG. 17 is a schematic cross-sectional view of an exemplary manufacturing step following the manufacturing step of FIG. 16.

FIG. 18 is a schematic cross-sectional view showing an exemplary manufacturing step for a nitride semiconductor device according to Embodiment 2.

FIG. 19 is a schematic cross-sectional view of an exemplary manufacturing step following the manufacturing step of FIG. 18.

FIG. 20 is a schematic cross-sectional view of an exemplary manufacturing step following the manufacturing step of FIG. 19.

FIG. 21 is a schematic cross-sectional view of an exemplary manufacturing step following the manufacturing step of FIG. 20.

FIG. 22 is a schematic cross-sectional view of an exemplary manufacturing step following the manufacturing step of FIG. 21.

FIG. 23 is a schematic cross-sectional view of an exemplary manufacturing step following the manufacturing step of FIG. 22.

FIG. 24 is a schematic cross-sectional view of an exemplary manufacturing step following the manufacturing step of FIG. 23.

FIG. 25 is a schematic cross-sectional view of an exemplary manufacturing step following the manufacturing step of FIG. 24.

FIG. 26 is a schematic cross-sectional view of an exemplary manufacturing step following the manufacturing step of FIG. 25.

FIG. 27 is a schematic cross-sectional view of an exemplary nitride semiconductor device according to Embodiment 3.

FIG. 28 is a schematic cross-sectional view of a nitride semiconductor device according to a modification example.

### DETAILED DESCRIPTION OF EMBODIMENTS

Some embodiments of in the nitride semiconductor device according to the present disclosure will be explained below with reference to attached drawings. In order to simplify and clarify the explanation, the constituent elements shown in the drawings are not necessarily depicted at a uniform scale. For ease of understanding, hatching lines are sometimes omitted from the cross-sectional views. The attached drawings are merely for the purpose of illustrating the embodiments of the present disclosure, and should not be interpreted as limiting the present disclosure.

Language such as “first,” “second,” “third,” or the like in the present disclosure is used merely in order to distinguish objects, and is not necessarily intended to indicate the sequence of the objects. For example, regarding a structure that includes a first element and a second element, there are cases in which the second element is mentioned without mentioning the first element in the claims. Additionally, in a structure in which the first element includes a first sub-element and the second element includes a second sub-element, there are cases in which the second sub-element of the second element is mentioned without mentioning the first sub-element of the first element in the claims.

The phrase “at least one” used in the present disclosure signifies “one or more” options among a plurality of desired options. As one example, if there are two options, then the phrase “at least one” signifies only one of the options or both options. As another example, if there are three or more options, then the phrase “at least one” signifies only one of the options, or a combination of any two or more options.

The detailed description below includes a device, a system, and a method for implementing exemplary embodiments of the present disclosure. The detailed description is typically for the sole purpose of explanation, and is not intended to limit the embodiments of the present disclosure, or to limit application and use of such embodiments.

### Embodiment 1

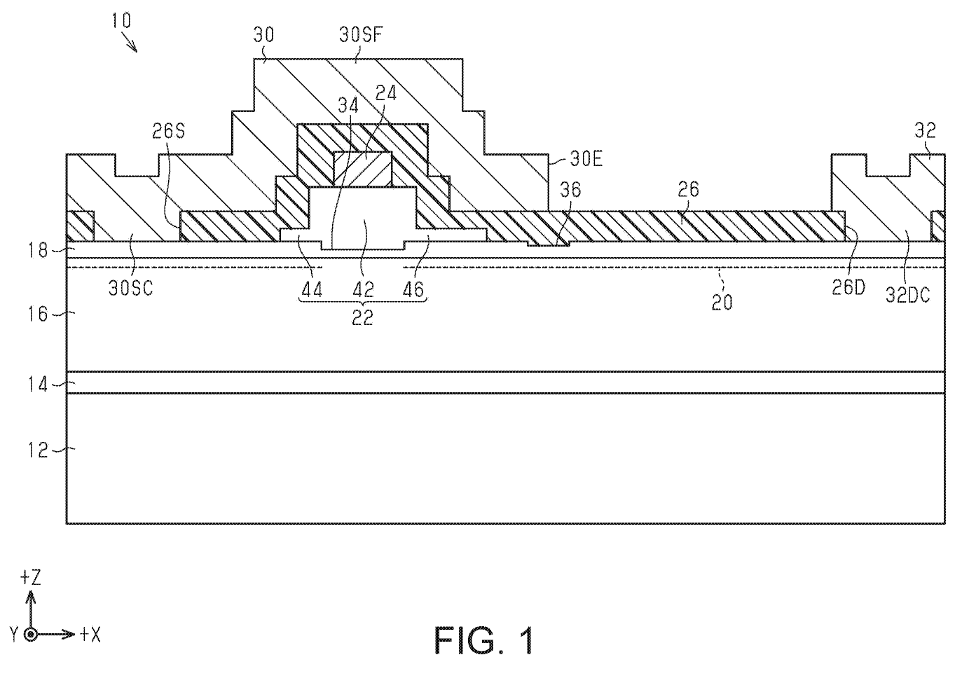

A nitride semiconductor device 10 according to Embodiment 1 will be described below with reference to FIGS. 1-17. In the present disclosure, components will be described on the basis of XYZ axes, which are perpendicular to each other, in the drawings. The term “plan view” used in the present disclosure indicates a view of the nitride semiconductor device 10 from the Z axis direction unless otherwise explicitly noted. In the description below, for ease of explanation, in the nitride semiconductor device 10 shown in FIG. 1, the +Z direction signifying the upward direction, the -Z direction signifying the downward direction, the +X direction signifying the rightward direction, and the -X direction signifying the leftward direction are sometimes used. However, the directions up, down, left, and right in relation to the nitride semiconductor device 10 are not limited to these directions.

### 1-1. Schematic Structure of Nitride Semiconductor Device

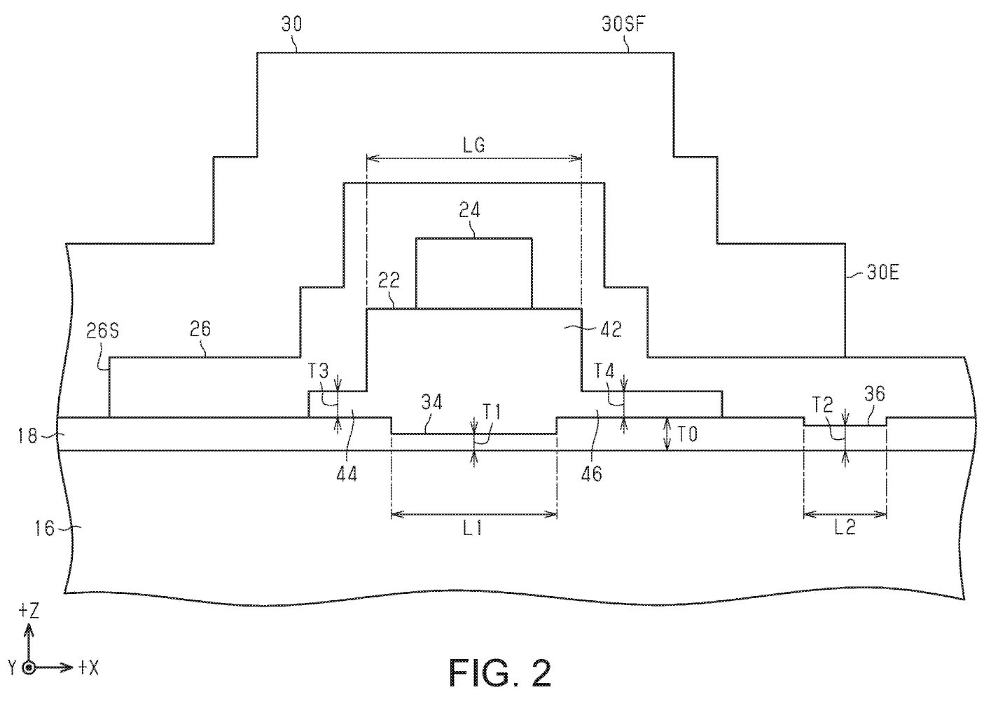

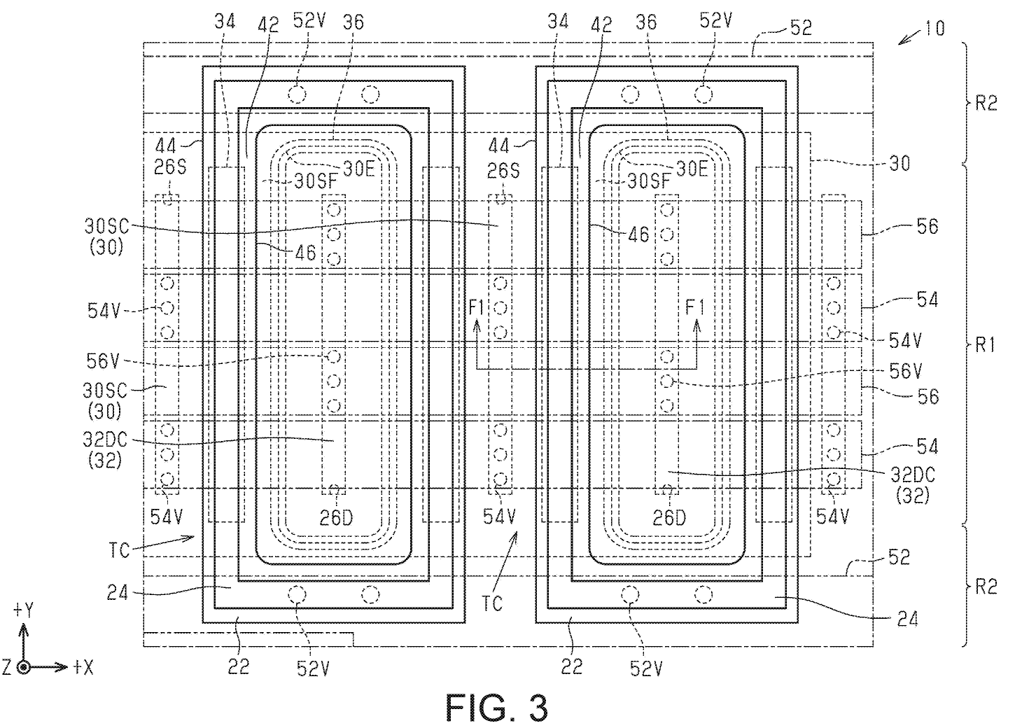

FIG. 1 is a schematic cross-sectional view of the nitride semiconductor device 10. FIG. 2 is a partial expanded cross-sectional view of the nitride semiconductor device 10, and FIG. 3 is a schematic plan view of the nitride semiconductor device 10. FIG. 1 is a cross-sectional view along the line F1-F1 of FIG. 3. The nitride semiconductor device 10 is configured as a HEMT using a nitride semiconductor. In one example, the nitride semiconductor device 10 is a GaN-HEMT that uses GaN. The GaN-HEMT is provided as a power transistor used for power device applications, for example.

As shown in FIG. 1, the nitride semiconductor device 10 includes a semiconductor substrate 12 and a buffer layer 14 positioned over the semiconductor substrate 12. The nitride semiconductor device 10 further includes an electron transport layer 16 and an electron supply layer 18 positioned over the electron transport layer 16.

The semiconductor substrate 12 can be made of Si, silicon carbide (SiC), GaN, sapphire, or another substrate material. In one example, the semiconductor substrate 12 is a conductive Si substrate. The thickness of the semiconductor substrate 12 can be 100μm to 1500μm, for example. In one example, the thickness of the semiconductor substrate 12 is 250μm.

The buffer layer 14 includes one or more nitride semiconductor layers. The electron transport layer 16 is positioned over the buffer layer 14. The buffer layer 14 can be constituted of any material that can facilitate epitaxial growth of the electron transport layer 16.

For example, the buffer layer 14 can include at least one of an aluminum nitride (AlN) layer, an aluminum gallium nitride (AlGaN) layer, and a graded AlGaN layer having a different Al composition. For example, the buffer layer 14 can be made of a single AlN layer, a single AlGaN layer, a layer having a superlattice structure of AlGaN/GaN, a layer having a superlattice structure of AlN/AlGaN, or a layer having an AlN/GaN superlattice structure. In order to suppress leakage current in the buffer layer 14, an impurity may be introduced in portions of the buffer layer 14 to make the buffer layer 14 semi-insulating. In this case, the impurity is carbon (C) or iron (Fe), and the impurity concentration can be set to 4×10¹⁶cm⁻³, for example.

The electron transport layer 16 may be a GaN layer, for example. The thickness of the electron transport layer 16 can be 0.5μm to 2μm, for example. In order to suppress leakage current in the electron transport layer 16, an impurity may be introduced in portions of the electron transport layer 16 to make areas other than the surface layer region of the electron transport layer 16 semi-insulating. In this case, the impurity is C, and the impurity concentration of the electron transport layer 16 can be set to 4×10¹⁶cm⁻³, for example.

The electron supply layer 18 has a greater bandgap than the electron transport layer 16. The electron supply layer 18 may be the AlGaN layer, for example. The greater the Al composition is, the greater the bandgap is, and thus, an electron supply layer 18 that is the AlGaN layer has a greater bandgap than an electron transport layer 16 that is a GaN layer. For example, the electron supply layer 18 is constituted of Al_{z}Ga_{(1-z)} with an Al composition rate z. The Al composition rate z is 0.1<z<0.4, for example, and preferably 0.1<z<0.3. The thickness of the electron supply layer 18 can be 5nm to 20nm, for example. In one example, the thickness of the electron supply layer 18 is 8nm or greater.

The electron transport layer 16 and the electron supply layer 18 are constituted of nitride semiconductors with different lattice constants. Thus, the nitride semiconductor (e.g., GaN) constituting the electron transport layer 16 and the nitride semiconductor (e.g., AlGaN) constituting the electron supply layer 18 form a heterojunction with a lattice mismatch. Through spontaneous polarization of the electron transport layer 16 and the electron supply layer 18 and piezo polarization resulting from crystal strain in the vicinity of the heterojunction interface, the energy level in the conduction band of the electron transport layer 16 in the vicinity of the heterojunction interface is lower than the Fermi level. As a result, a 2DEG 20 spreads in the electron transport layer 16 at a position close to the heterojunction interface between the electron transport layer 16 and the electron supply layer 18 (e.g., within a range of several nm of the interface).

The nitride semiconductor device 10 further includes a gate layer 22 located at a portion over the electron supply layer 18 and a gate electrode 24 located at a portion over the gate layer 22.

The gate layer 22 is constituted of a nitride semiconductor including an acceptor impurity. The gate layer 22 may be a GaN layer doped with the acceptor impurity (p-type GaN layer), for example. The acceptor impurity can include at least one of zinc (Zn), magnesium (Mg), and carbon (C). The maximum concentration of the acceptor impurity in the gate layer 22 may be 1×10¹⁸cm⁻³ to 1×10²⁰cm⁻³, for example.

The gate electrode 24 includes one or more metal layers. In one example, the gate electrode 24 is a titanium nitride (TiN) layer. In another example, the gate electrode 24 includes a first metal layer made of Ti, and a second metal layer positioned over the first metal layer and made of TiN. The gate electrode 24 is in a Schottky junction with the gate layer 22. The thickness of the gate electrode 24 can be 50nm to 200nm, for example.

The nitride semiconductor device 10 further includes a passivation layer 26. The passivation layer 26 covers the electron supply layer 18, the gate layer 22, and the gate electrode 24. The passivation layer 26 is made of at least one of silicon nitride (SiN), silicon dioxide (SiO₂), silicon oxynitride (SiON), alumina (Al₂O₃), AlN, and aluminum oxynitride (AlON), for example. In one example, the passivation layer 26 may be made of a material including SiN. The thickness of the passivation layer 26 can be 50nm to 150nm and formed over the electron supply layer 18, for example.

The passivation layer 26 includes a source opening 26S and a drain opening 26D that are separated from each other in a first direction (X axis direction in FIG. 1) in a plan view. The gate layer 22 is positioned between the source opening 26S and the drain opening 26D in the first direction. The gate layer 22 is positioned closer to the source opening 26S than to the drain opening 26D.

Below, for ease of description, the direction in which the source opening 26S, the gate layer 22, and the drain opening 26D are aligned in a plan view (X axis direction in FIG. 1) is referred to as a first direction X, and the direction intersecting with the first direction X in a plan view (the Y axis direction perpendicular to the X axis direction in FIG. 1) is referred to as a second direction Y.

The nitride semiconductor device 10 further includes a source electrode 30 in contact with the electron supply layer 18 via the source opening 26S, and a drain electrode 32 in contact with the electron supply layer 18 via the drain opening 26D. The source electrode 30 and the drain electrode 32 can each include one or more metal layers. For example, the source electrode 30 and the drain electrode 32 can each be made of a combination of two or more metal layers selected from a group including a Ti layer, a TiN layer, an Al layer, an AlSiCu layer, an AlCu layer, and the like. In one example, the source electrode 30 and the drain electrode 32 each have a four-layer structure (Ti layer/AlCu layer/Ti layer/TiN layer) including the Ti layer, the AlCu layer, the Ti layer, and the TiN layer in the stated order from the top.

The source electrode 30 includes a source contact section 30SC that fills the source opening 26S and is in contact with the electron supply layer 18, and a field plate section 30SF that is formed integrally with the source contact section 30SC and is positioned over the passivation layer 26. The source contact section 30SC is in ohmic contact with the 2DEG 20 directly below the electron supply layer 18 via the source opening 26S.

The field plate section 30SF covers the entirety of the gate electrode 24 and the gate layer 22, for example, in a plan view. The field plate section 30SF includes a field plate end section 30E that opposes the drain electrode 32. The field plate section 30SF has the role of mitigating the concentration of an electric field in the vicinity of the ends of the gate layer 22 when a high voltage is applied between the source and drain during the OFF state when the 2DEG 20 in the region of the electron transport layer 16 directly below the gate layer 22 is absent.

The drain electrode 32 includes a drain contact section 32DC that fills the drain opening 26D and is in contact with the electron supply layer 18. The drain contact section 32DC is in ohmic contact with the 2DEG 20 directly below the electron supply layer 18 via the drain opening 26D.

In the nitride semiconductor device 10, the electron transport layer 16, the electron supply layer 18, the gate layer 22, the gate electrode 24, the source electrode 30, and the drain electrode 32 constitute a transistor (HEMT). In this configuration, the energy level of the electron transport layer 16 and the electron supply layer 18 is raised as a result of the acceptor impurity being included in the gate layer 22. Thus, in the region directly below the gate layer 22, the energy level of the conduction band of the electron transport layer 16 in the vicinity of the heterojunction interface between the electron transport layer 16 and the electron supply layer 18 is substantially equal to the Fermi level or greater than the Fermi level. As a result, when a gate control voltage that turns OFF the transistor is applied to the gate electrode 24 (e.g., when the gate-source voltage is 0V or less), then the 2DEG 20 is not formed in the region of the electron transport layer 16 directly below the gate layer 22. Meanwhile, the 2DEG 20 is formed in regions of the electron transport layer 16 other than the region directly below the gate layer 22.

Thus, as a result of the presence of the gate layer 22 doped with the acceptor impurity, the 2DEG 20 is absent from the region of the electron transport layer 16 directly below the gate layer 22, thereby allowing for the realization of a normally OFF operation for the HEMT. When a suitable gate control voltage (ON voltage) is applied to the gate electrode 24, a channel resulting from the 2DEG 20 is formed in the region of the electron transport layer 16 directly below the gate layer 22, thereby causing conduction between the source and drain.

### 1-2. Stepped Structure of Gate Layer

Next, with reference to FIG. 1, a stepped structure of the gate layer 22 will be described. In the nitride semiconductor device 10 according to Embodiment 1, the gate layer 22 has a stepped structure including a gate layer main body section 42, a source-side extending section 44, and a drain-side extending section 46. The source-side extending section 44 extends from the gate layer main body section 42 towards the source contact section 30SC in the first direction X. The drain-side extending section 46 extends from the gate layer main body section 42 towards the drain contact section 32DC in the first direction X.

The gate layer main body section 42 has, for example, a ridge shape, a rectangular shape or a trapezoidal shape in a cross-sectional view . The gate electrode 24 is positioned over a portion over the gate layer main body section 42. The source-side extending section 44 and the drain-side extending section 46 are each thinner than the gate layer main body section 42.

The thickness of the gate layer main body section 42 is 100nm to 200nm, for example. The thickness of the gate layer main body section 42 is defined as the distance from the top surface of the gate layer main body section 42 to the bottom surface of the gate layer main body section 42 in contact with the top surface of the electron supply layer 18. The thickness of the gate layer main body section 42 can be determined in consideration of various parameters such as the gate withstand voltage.

Meanwhile, the thicknesses of the source-side extending section 44 and the drain-side extending section 46 may be 10nm to 30nm, for example. The thickness of the source-side extending section 44 and the thickness of the drain-side extending section 46 may be equal to or differ from each other. As an example, the source-side extending section 44 has the same thickness as the drain-side extending section 46. The drain-side extending section 46 has a greater length in the first direction X than the source-side extending section 44.

In the gate layer 22 having such a stepped section, the source-side extending section 44 and the drain-side extending section 46 have the role of suppressing the concentration of an electric field in the vicinity of the edges of the gate layer 22 and the vicinity of the edges of the gate electrode 24.

### 1-3. Recessed Structure of Electron Supply Layer

Next, with reference to FIG. 2, a recessed structure of the electron supply layer 18 will be described. The electron supply layer 18 includes a first recess 34 and a second recess 36 that are formed in the top surface of the electron supply layer 18. The first recess 34 is provided in a section of the top surface of the electron supply layer 18 overlapping the gate layer 22 in a plan view. The second recess 36 is provided in a section of the top surface of the electron supply layer 18 overlapping the field plate end section 30E in a plan view.

The first recess 34 can have a length less than that of the gate layer 22 in the first direction X. If, for example, the gate layer main body section 42 has a main body section length LG in the first direction X, then the first recess 34 can have a first recess length L1 less than the main body section length LG in the first direction X. In Embodiment 1, the first recess 34 overlaps the gate layer main body section 42 in a plan view, and does not extend outside of the gate layer main body section 42. Thus, the entirety of the first recess 34 overlaps the gate layer main body section 42 in a plan view.

The first recess 34 is provided as a means to mitigate a decrease in the gate threshold. This will be explained below. In a normally OFF HEMT, as described above, the energy levels of the electron transport layer 16 and the electron supply layer 18 are raised by the acceptor impurity in the gate layer 22 such that the energy level of the conduction band of the electron transport layer 16 in the vicinity of the heterojunction interface increases to greater than the Fermi level. Thus, as a result of the 2DEG 20 being absent directly below the gate layer 22, the transistor is kept OFF. If, in this case, the electron supply layer 18 is too thick, then the raising of the energy level of the conduction band of the electron transport layer 16 in relation to the Fermi level is insufficient, thus causing a decrease in the gate threshold. Therefore, if the electron supply layer 18 is thickened in order to improve the gate-source withstand voltage (hereinafter referred to as the “GS withstand voltage), this results in the trade-off of a decreased gate threshold. In consideration of this point, the first recess 34 is provided in a section of the top surface of the electron supply layer 18 overlapping the gate layer 22 in a plan view in order to mitigate a decrease in gate threshold.

Here, the first recess 34 overlaps the gate layer main body section 42, which contributes to determining the gate threshold, in a plan view, but does not overlap the source-side extending section 44 or the drain-side extending section 46 in a plan view. A gate leakage current (Igss), which is a cause for a decrease in the GS withstand voltage, passes through a portion of the electron supply layer 18 directly below the end of the source-side extending section 44 as a leakage current path between the electron transport layer 16 and the gate layer 22, for example. Thus, by thickening the portion of the electron supply layer 18 directly below the end of the source-side extending section 44, it is possible to mitigate a decrease in GS withstand voltage resulting from the gate leakage current. Therefore, by maintaining the thickness of the electron supply layer 18 directly below the source-side extending section 44 while mitigating a decrease in gate threshold by decreasing the thickness of the electron supply layer 18 in the portion that has an effect on the gate threshold, it is possible to keep the GS withstand voltage at a target value.

A thickness T0 of the electron supply layer 18 (thickness of the section where the first and second recesses 34 and 36 are not present) can be 5nm to 20nm as described above, for example. By contrast, a thickness T1 of the electron supply layer 18 in the first recess 34 can be set to any value based on the design of the gate threshold as long as the thickness T1 is less than the thickness T0 of the electron supply layer 18. The main body section length LG of the gate layer main body section 42 may be 400nm to 800nm, for example, and the first recess length L1 may be 300nm to 600nm, for example. In one example, the main body section length LG is 700nm and the first recess length L1 is 500nm.

The first recess length L1 is not necessarily limited to being less than the main body section length LG. For example, the first recess length L1 may be greater than or equal to the main body section length LG. However, from the perspective of mitigating an increase in ON resistance while maintaining the sheet carrier density of the 2DEG 20 in the regions directly below the source-side extending section 44 and the drain-side extending section 46, it is preferable that the first recess length L1 be less than the main body section length LG.

The second recess 36 can have a second recess length L2 less than a first recess length L1 in the first direction X. The second recess 36 overlaps the field plate end section 30E in a plan view, but does not overlap the gate layer 22 in a plan view. The second recess 36 should have the minimum length (second recess length L2) necessary to sufficiently cover the field plate end section 30E even in cases of positional offset thereof in the first direction X resulting from the manufacturing process or the like, for example.

The second recess 36 is provided as a means to mitigate a decrease in the drain-source withstand voltage (hereinafter referred to as the “DS withstand voltage”). This will be explained below. The field plate 30SF has the role of improving the DS withstand voltage by mitigating the concentration of an electric field in the vicinity of the ends of the gate layer 22, and in particular, the vicinity of the end of the drain-side extending section 46 in Embodiment 1 shown in FIG. 2. In this case, if the electron supply layer 18 is too thick, then as a result of the sheet carrier density of the 2DEG 20 becoming too high, easing of the concentration of the electric field by the field plate 30SF would be insufficient. Therefore, if the electron supply layer 18 is thickened in order to improve the GS withstand voltage as described above, this results in the trade-off of a decreased DS withstand voltage. In consideration of this point, the second recess 36 is provided in a section of the top surface of the electron supply layer 18 overlapping the field plate end section 30E in a plan view in order to mitigate a decrease in the DS withstand voltage while limiting an excessive increase in the sheet carrier density.

The second recess 36 has the role of limiting an excessive increase in the sheet carrier density of the 2DEG 20, but if the second recess length L2 becomes large, this results in an increase in ON resistance due to a decrease in the sheet carrier density. Thus, the second recess length L2 simply needs to be large enough to cover the field plate end section 30E even in the case of positional offset, and may be 200nm to 600nm, for example. In one example, the second recess length L2 is 300nm.

A thickness T2 of the electron supply layer 18 in the second recess 36 can be set to any value based on the design of the DS withstand voltage as long as the thickness T2 is less than the thickness T0 of the electron supply layer 18. The thickness T2 may be the same as or differ from the thickness T1 of the electron supply layer 18 in the first recess 34. In the example of FIG. 2, by setting the thickness T1 as small as possible in order to attain as high a gate threshold as possible, the thickness T1 is set to be less than the thickness T2. However, the thickness T1 may be set to be greater than or equal to the thickness T2 according to the design of the gate threshold and the DS withstand voltage. The thickness T3 of the source-side extending section 44 and the thickness T4 of the drain-side extending section 46 are respectively greater than the thickness T1 and greater than the thickness T2. As described above, the thickness T3 and the thickness T4 may be 10nm to 30nm, for example.

### 1-4. Plan View Layout of Nitride Semiconductor Device

Next, an exemplary plan view layout of the nitride semiconductor device 10 will be explained with reference to FIG. 3. In FIG. 3, the outer shape of the source electrode 30 and the source opening 26S and the drain opening 26D of the passivation layer 26 are depicted with broken lines. In order to indicate the constituent elements in an easy to understand manner, some components such as the passivation layer 26 are depicted to be transparent in FIG. 3.

As shown in FIG. 3, the gate layer 22 has a loop shape that surrounds the drain contact section 32DC (drain electrode 32) in a plan view. The gate electrode 24 overlaps the gate layer 22 in a plan view and covers the top surface of the gate layer 22. Therefore, the gate electrode 24 also has a loop shape that surrounds the drain contact section 32DC (drain electrode 32) in a plan view.

The first recess 34 overlaps the gate layer main body section 42 of the gate layer 22. In order to prevent the depiction from being too complex, in FIG. 3, the step between the gate layer main body section 42 and the source-side extending section 44 is omitted, and the step between the gate layer main body section 42 and the drain-side extending section 46 is also omitted.

The first recess 34 is disposed only in an active region R1 of the nitride semiconductor device 10, for example. In the example of FIG. 2, the first recess 34 extends in the second direction Y while overlapping the gate layer main body section 42 in the active region R1. The active region R1 is the region that primarily contributes to the operation of the HEMT, and covers a range in which the drain electrode 32 extends in the second direction Y, for example. The active region R1 is adjacent to non-active regions R2 in the second direction Y, and thus, the active region R1 and the non-active regions R2 alternate in the second direction Y. The first recess 34 contributes to determining the gate threshold as described above, and thus, should be present at least in the active region R1.

The second recess 36 spans both the active region R1 and the non-active region R2. In other words, the second recess 36 overlaps the entire loop of the field plate end section 30E of the field plate section 30SF, which spans both the active region R1 and the non-active region R2. Since the second recess 36 contributes to determining the DS withstand voltage as described above, it is preferable that the second recess 36 span both the active region R1 and the non-active region R2.

The nitride semiconductor device 10 includes gate wiring line sections 52, source wiring line sections 54, and drain wiring line sections 56 depicted with dashed-dotted lines in FIG. 3. The gate wiring line sections 52, the source wiring line sections 54, and the drain wiring line sections 56 are positioned above the gate electrode 24, the source electrode 30, and the drain electrode 32 in the Z axis direction (direction perpendicular to both the first direction X and the second direction Y). The gate wiring line sections 52, the source wiring line sections 54, and the drain wiring line sections 56 extend above the gate electrode 24, the source electrode 30, and the drain electrode 32 in the first direction X, for example. The gate wiring line section 52, the source wiring line section 54, and the drain wiring line section 56 are made of a conductive material such as gold (Au), Cu, Al, or the like, for example.

The gate electrode 24 is electrically connected to the gate wiring line sections 52 by a plurality of connective conductors 52V disposed over the gate electrode 24. The source electrode 30 is electrically connected to the source wiring line sections 54 by a plurality of connective conductors 54V disposed over the source electrode 30 above the source contact section 30SC, for example. The drain electrode 32 is electrically connected to the drain wiring line sections 56 by a plurality of connective conductors 56V disposed over the drain electrode 32 above the drain contact section 32DC, for example.

The nitride semiconductor device 10 includes a plurality of the transistor cells TC. In FIG. 3, a plurality of the transistor cells TC arrayed along the first direction X are shown, but the plurality of transistor cells TC may also be arrayed along the second direction Y. FIG. 1 shows one cross-sectional structure of the plurality of transistor cells TC included in the nitride semiconductor device 10. The plan view layout of the nitride semiconductor device 10 (transistor cells TC) shown in FIG. 3 is merely one example, and other plan view layouts may be used for the nitride semiconductor device 10.

### 1-5. Manufacturing Method for Nitride Semiconductor Device

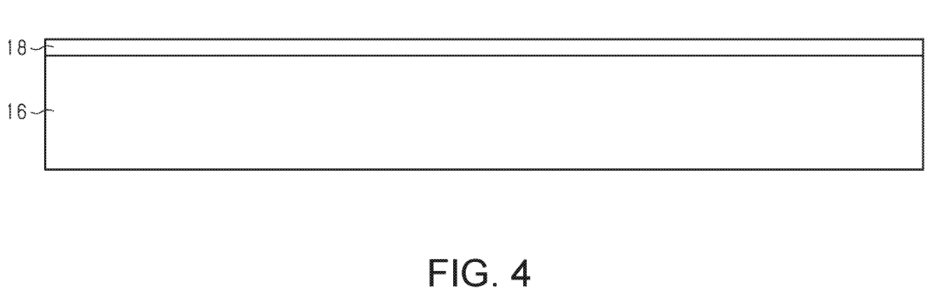

Next, the manufacturing method for the nitride semiconductor device 10 will be explained with reference to FIGS. 4-17. FIGS. 4-17 are schematic cross-sectional views showing an exemplary manufacturing step for the nitride semiconductor device 10 shown in FIG. 1. For ease of understanding, constituent elements similar to those of the nitride semiconductor device 10 of FIG. 1 are assigned the same reference characters. In FIGS. 4-17, in order to make the depiction easier to understand, the semiconductor substrate 12 and the buffer layer 14 of FIG. 1 are omitted from the depiction.

As shown in FIG. 4, the manufacturing method for the nitride semiconductor device 10 includes forming the buffer layer 14 (see FIG. 1), the electron transport layer 16, and the electron supply layer 18 in the stated order over the semiconductor substrate 12 (see FIG. 1), which is an Si substrate, for example. The buffer layer 14, the electron transport layer 16, and the electron supply layer 18 can be subjected to epitaxial growth by metal organic chemical vapor deposition (MOCVD).

Although omitted from the depiction, in one example, the buffer layer 14 (see FIG. 1) may be a multilayer buffer layer. The multilayer buffer layer can include an AlN layer (first buffer layer) formed over the semiconductor substrate 12 (see FIG. 1), and a graded AlGaN layer (second buffer layer) formed over the AlN layer. The graded AlGaN layer can be formed by stacking three AlGaN layers in which the Al composition is 75%, 50%, and 25%, respectively, in the stated order from the AlN layer, for example.

The electron transport layer 16 is a GaN layer, for example. The electron supply layer 18 formed over the electron transport layer 16 is an AlGaN layer, for example. Thus, the electron supply layer 18 is constituted of a nitride semiconductor having a greater bandgap than the electron transport layer 16.

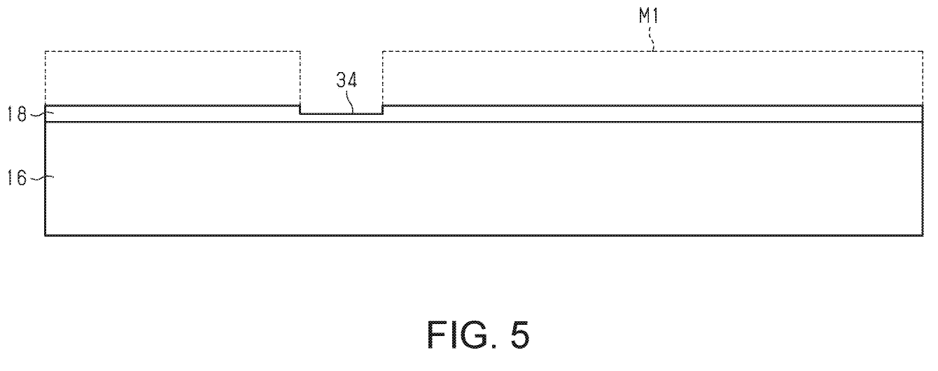

Next, in the manufacturing step shown in FIG. 5, a mask M1 formed over the electron supply layer 18 is used to etch a portion of the electron supply layer 18 to a given depth, thereby forming the first recess 34. Then, the mask M1 is removed. At this time, the etching depth is determined such that the thickness T1 (see FIG. 2) of the electron supply layer 18 in the first recess 34 is a target thickness based on the design of the gate threshold.

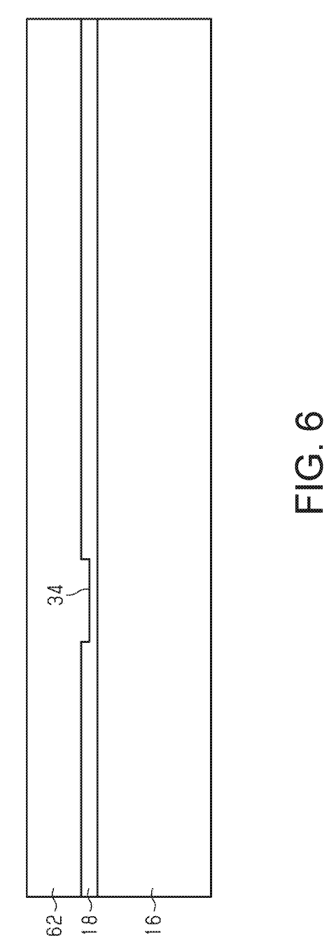

Next, in the manufacturing step shown in FIG. 6, a nitride semiconductor layer 62 is formed over the electron supply layer 18. The nitride semiconductor layer 62 is for forming the gate layer 22 described with reference to FIG. 1, and is formed by epitaxial growth by MOCVD. The nitride semiconductor layer 62 is a p-type GaN layer, for example. By regrowing the nitride semiconductor layer 62 over the electron supply layer 18, the nitride semiconductor layer 62 fills the first recess 34.

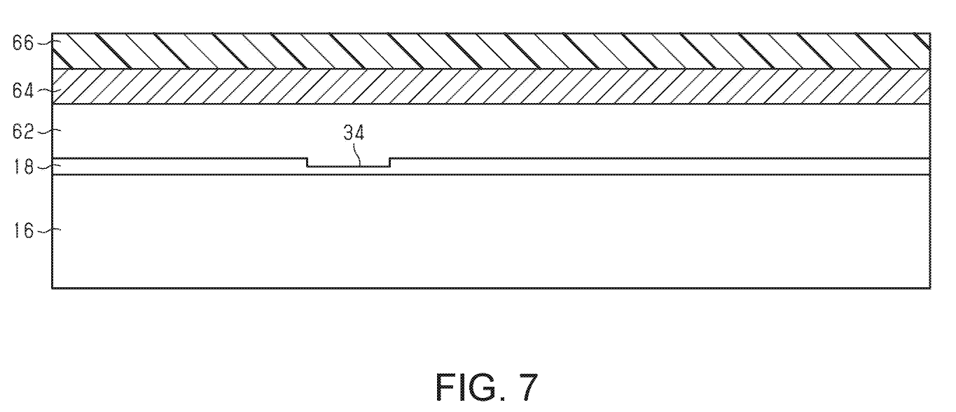

Next, in the manufacturing step shown in FIG. 7, an electrode layer 64 and a protective layer 66 are sequentially formed over the nitride semiconductor layer 62. The electrode layer 64 is for forming the gate electrode 24 described with reference to FIG. 1, and is formed by sputtering, for example. In one example, the electrode layer 64 is a TiN layer. The protective layer 66 is, for example, formed by plasma-enhanced chemical vapor deposition (PECVD), and in one example is a SiN layer.

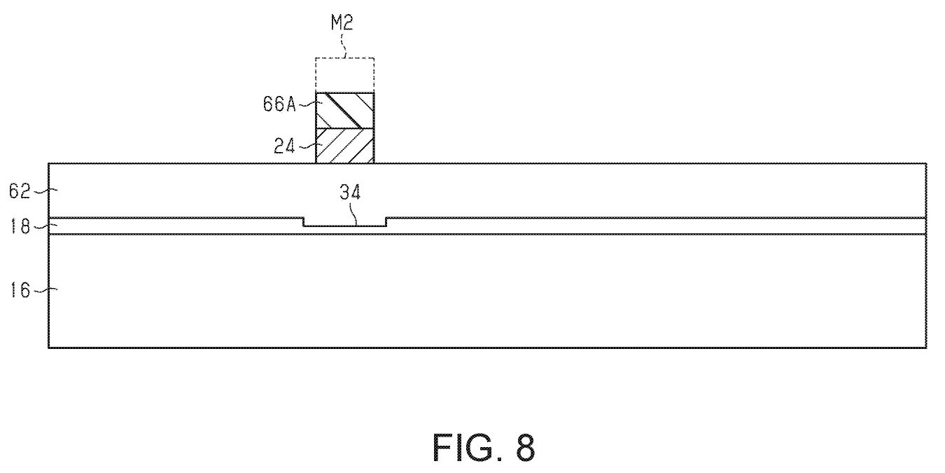

Next, in the manufacturing step shown in FIG. 8, the electrode layer 64 and the protective layer 66 are selectively removed by lithography and etching. In this step, a mask M2 is formed over the portion of the protective layer 66 corresponding to the region in which the gate electrode 24 is formed, and portions of the electrode layer 64 and the protective layer 66 not covered by the mask M2 are selectively removed. As a result, a protective section 66A is left remaining directly below the mask M2, and the gate electrode 24 is formed directly below the protective section 66A. Then, the mask M2 is removed.

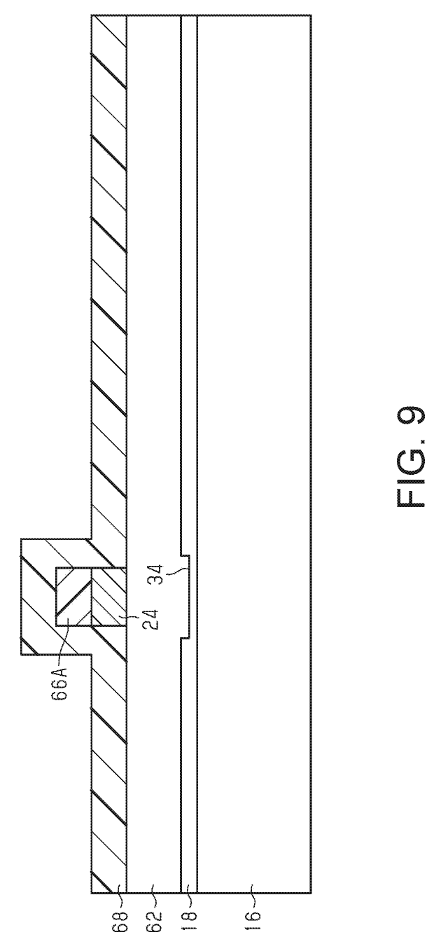

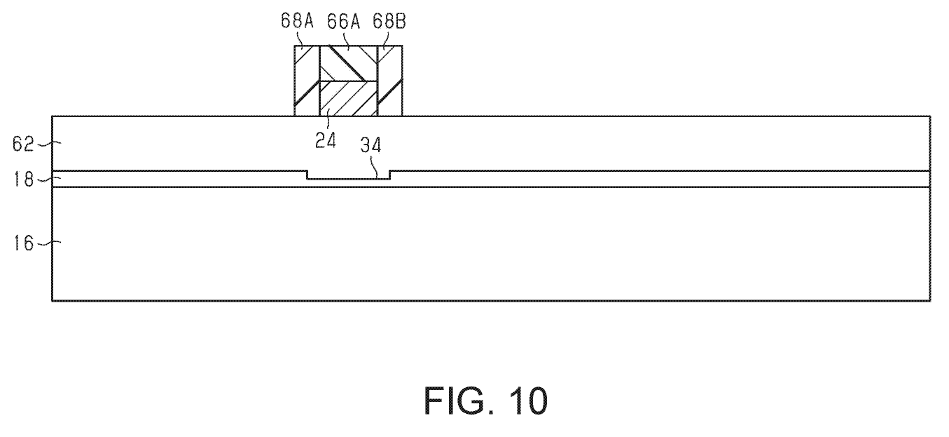

Next, in the manufacturing step shown in FIG. 9, a protective layer 68 covering the gate electrode 24 and the protective section 66A is formed over the nitride semiconductor layer 62. The protective layer 68 is, for example, formed by PECVD, and in one example is an SiN layer. Next, in the manufacturing step shown in FIG. 10, the protective layer 68 is etched back until the top surface of the nitride semiconductor layer 62 is exposed. As a result of the protective layer 68 being etched back, protective walls 68A and 68B covering the side walls of both the gate electrode 24 and the protective section 66A are formed.

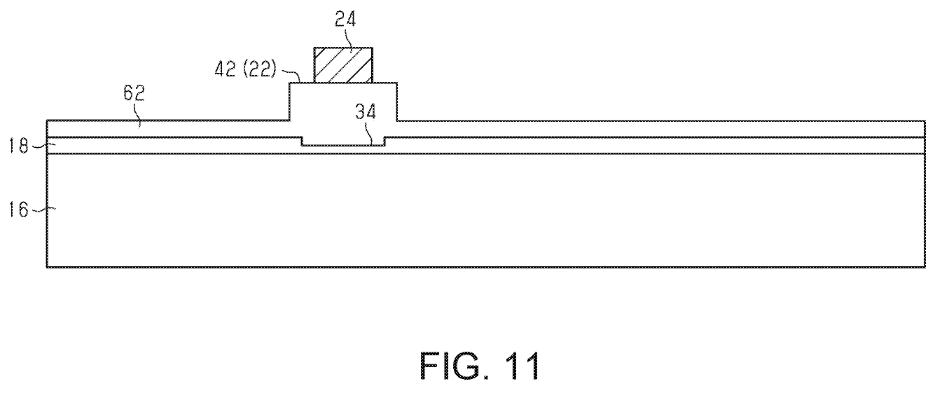

In the manufacturing step shown in FIG. 11, by etching (e.g., dry etching) the nitride semiconductor layer 62 to a given depth using the above-mentioned protective section 66A and the protective walls 68A and 68B as masks, the gate layer main body section 42 of the gate layer 22 is formed. In this step, a thinned portion of the nitride semiconductor layer 62 having a thickness corresponding to the source-side extending section 44 and the drain-side extending section 46 described with reference to FIG. 1 is left remaining on both sides of the gate layer main body section 42. Then, the protective section 66A and the protective walls 68A and 68B are removed.

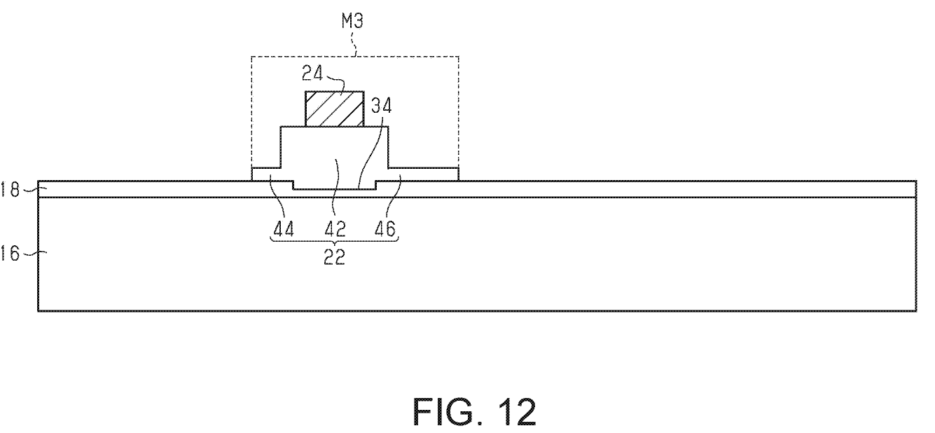

Next, in the manufacturing step shown in FIG. 12, by selectively etching the thinned portions of the nitride semiconductor layer 62 (see FIG. 11) using a mask M3 that covers the gate electrode 24 and the gate layer main body section 42, the source-side extending section 44 and the drain-side extending section 46 are formed. Then, the mask M3 is removed.

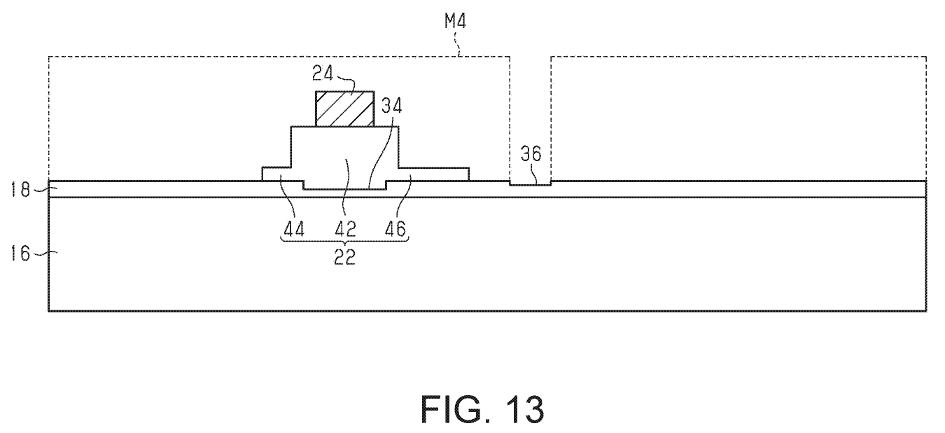

Next, in the manufacturing step shown in FIG. 13, a mask M4 covering the gate electrode 24 and the gate layer 22 (gate layer main body section 42, source-side extending section 44, and drain-side extending section 46) is used to etch a portion of the electron supply layer 18 to a given depth, thereby forming the second recess 36. Then, the mask M4 is removed. At this time, the etching depth is determined such that the thickness T2 (see FIG. 2) of the electron supply layer 18 in the second recess 36 is a target thickness based on the design of the DS withstand voltage.

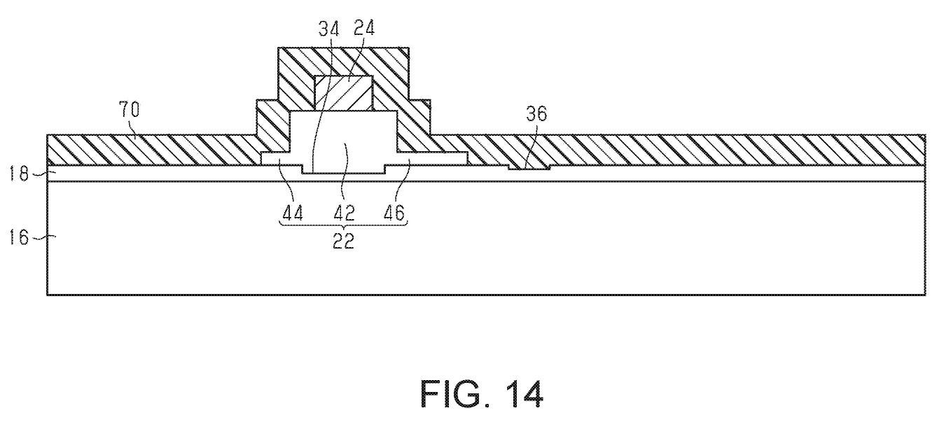

Next, in the manufacturing step shown in FIG. 14, an insulating layer 70 that covers the electron supply layer 18, the gate layer 22, and the gate electrode 24 is formed. The insulating layer 70 is for forming the passivation layer 26 described with reference to FIG. 1, and in one example is an SiN layer. The insulating layer 70is formed by low-pressure chemical vapor deposition (LPCVD), for example.

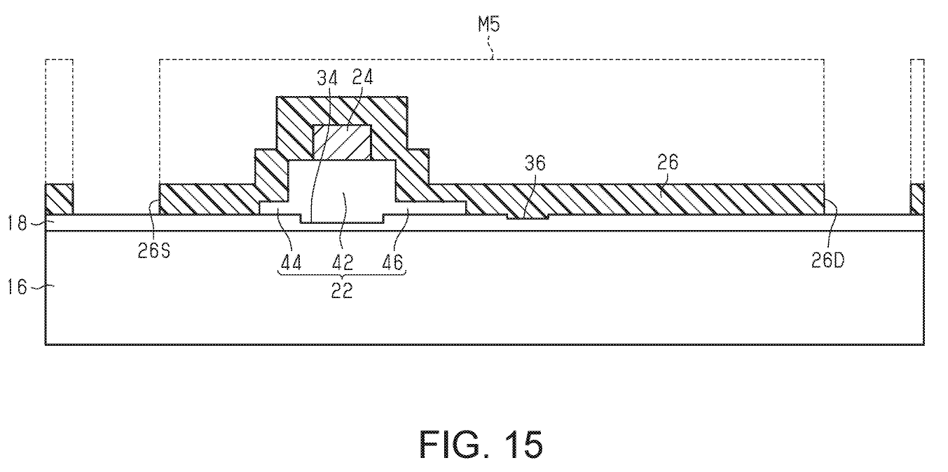

Next, in the manufacturing step shown in FIG. 15, the insulating layer 70 is selectively etched using a mask M5 formed over the insulating layer 70, thereby forming the passivation layer 26 including the source opening 26S and the drain opening 26D.

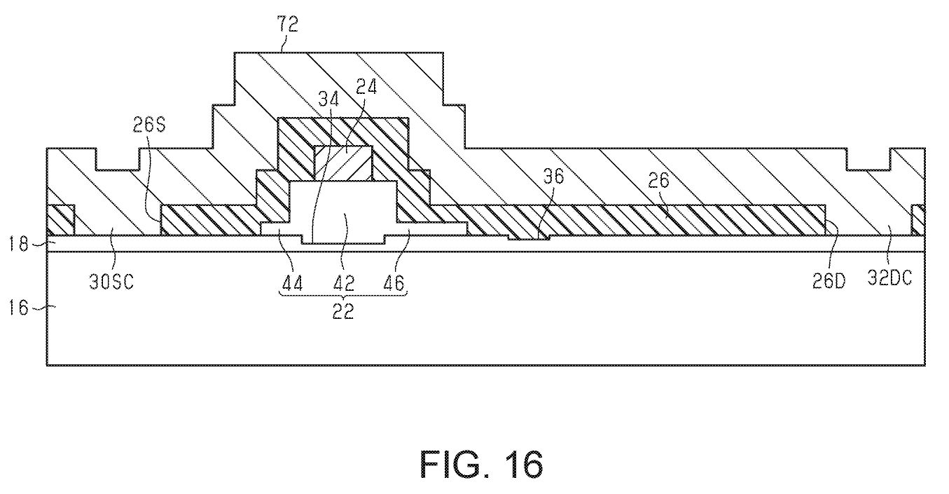

Next, in the manufacturing step shown in FIG. 16, an electrode layer 72 that fills the source opening 26S and the drain opening 26D is formed over the passivation layer 26. The electrode layer 72 is for forming the source electrode 30 and the drain electrode 32 described with reference to FIG. 1, and is formed by sputtering, for example. By forming the electrode layer 72, the source contact section 30SC fills the source opening 26S and the drain contact section 32DC fills the drain opening 26D. In one example, the electrode layer 72 has a four-layer structure (Ti layer/AlCu layer/Ti layer/TiN layer).

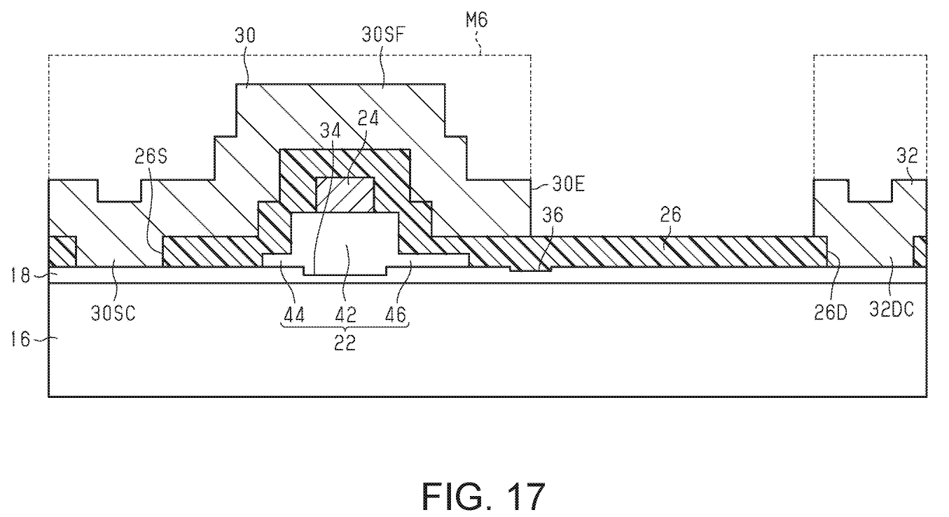

Next, in the manufacturing step shown in FIG. 17, the electrode layer 72 is selectively etched using a mask M6 formed over the electrode layer 72 (see FIG. 16), thereby forming the source electrode 30 (including the field plate section 30SF) and the drain electrode 32. By the above manufacturing steps, the nitride semiconductor device 10 shown in FIG. 1 can be manufactured.

### 1-6. Action of Nitride Semiconductor Device

In HEMTs in general, if the thickness of the electron supply layer is increased in order to improve the gate withstand voltage, this can result in a decrease in the gate threshold as well as a reduction in drain-source withstand voltage (DS withstand voltage), and there can be a trade-off therebetween. In consideration of this point, the electron supply layer 18 of the nitride semiconductor device 10 has the first recess 34 overlapping the gate layer 22 in a plan view, and the second recess 36 overlapping the field plate end section 30E of the field plate 30SF in a plan view.

The first recess 34 is provided as a means to mitigate a decrease in the gate threshold. By controlling the thickness of the electron supply layer 18 in the region directly below the gate layer 22 by the depth of the first recess 34, a reduction in energy level of the conduction band of the electron transport layer 16, which is raised relative to the Fermi level by an acceptor impurity in the gate layer 22, is mitigated. As a result, it is possible to mitigate a decrease in gate threshold.

Here, the first recess 34 overlaps the gate layer main body section 42 in a plan view, but does not overlap the source-side extending section 44 or the drain-side extending section 46 in a plan view. The gate leakage current, which is a cause for a decrease in the gate withstand voltage (GS withstand voltage), passes through a portion of the electron supply layer 18 directly below the end of the source-side extending section 44 as a leakage current path. In consideration of this point, the first recess 34 is provided only directly below the gate layer main body section 42, which contributes to determining the gate threshold. As a result, by maintaining the thickness of the portion of the electron supply layer 18 directly below the end of the source-side extending section 44, it is possible to achieve a balance between improvement in the gate withstand voltage and a decrease in gate threshold.

The second recess 36 is provided as a means to mitigate a decrease in the DS withstand voltage. By controlling the thickness of the electron supply layer 18 in the region directly below the field plate end section 30E by the depth of the second recess 36, an excessive increase in the sheet carrier density of the 2DEG 20 can be mitigated. As a result, it is possible to mitigate a decrease in the DS withstand voltage by maintaining the function of the field plate 30SF of suppressing the concentration of an electric field.

### 1-7. Advantages of Nitride Semiconductor Device

The nitride semiconductor device 10 has the following advantages.

(1-1) The electron supply layer 18 includes the first recess 34 overlapping the gate layer 22 in a plan view. By providing the first recess 34 directly below the gate layer 22, it is possible to mitigate a decrease in gate threshold while achieving an improvement in gate withstand voltage (GS withstand voltage) by thickening the electron supply layer 18. Also, the electron supply layer 18 includes the second recess 36 overlapping the field plate end section 30E in a plan view. By providing this second recess 36, it is possible to mitigate a decrease in the DS withstand voltage by maintaining the function of the field plate 30SF of suppressing the concentration of an electric field. As a result, it is possible achieve an increase in gate withstand voltage while mitigating a decrease in the gate threshold and a decrease in the DS withstand voltage.

(1-2) The first recess 34 overlaps the gate layer main body section 42 of the gate layer 22 in a plan view, and the first recess length L1 (length of the first recess 34 in the first direction X) is less than the main body section length LG (length of the gate layer main body section 42 in the first direction X). Thus, the first recess 34 does not overlap the source-side extending section 44 or the drain-side extending section 46 in a plan view. According to this configuration, by providing the first recess 34 directly below the gate layer main body section 42, which contributes to determining the gate threshold, it is possible to maintain the gate withstand voltage (GS withstand voltage) by maintaining the thickness of the electron supply layer 18 in the leakage current path for the gate leakage current (Igss).

(1-3) The second recess length L2 (length of the second recess 36 in the first direction X) is less than the first recess length L1. The second recess length L2 is set to the minimum length necessary to sufficiently cover the field plate end section 30E even in cases of positional offset thereof in the first direction X resulting from the manufacturing process, for example. As a result, it is possible to mitigate a greater than necessary decrease in the sheet carrier density of the 2DEG 20 using the second recess 36, and thereby suppress an increase in ON resistance.

(1-4) The thickness T1 of the electron supply layer 18 in the first recess 34 differs from the thickness T2 of the electron supply layer 18 in the second recess 36. The thickness T1 (i.e., the depth of the first recess 34) can be determined according to the design of the gate threshold. On the other hand, the thickness T2 (i.e., the depth of the second recess 36) can be determined according to the design of the DS withstand voltage. In one example, the thickness T1 is set so as to be less than the thickness T2. As a result, it is possible to suppress to a minimum an increase in ON resistance resulting from providing the second recess 36 while realizing the desired gate threshold by providing the first recess 34.

(1-5) The second recess 36 is formed in a step differing from the step in which the first recess 34 is formed. In Embodiment 1, the first recess 34 is formed in the electron supply layer 18 (see FIG. 5), the nitride semiconductor layer 62 is regrown over the electron supply layer 18 (see FIG. 6), and the gate layer 22 is formed from the nitride semiconductor layer 62 (see FIG. 12), after which the second recess 36 is formed in the electron supply layer 18. If, for example, the second recess 36 were to be formed simultaneously to the formation of the first recess 34, this can result in nitrogen desorption from the second recess 36 region of the electron supply layer 18 during regrowth of the nitride semiconductor layer 62. Nitrogen desorption can cause the formation of electron traps in the second recess 36 at the region between the gate and drain of the electron supply layer 18, which can cause current collapse. In the manufacturing steps described above, the second recess 36 is formed after regrowth of the nitride semiconductor layer 62, which prevents such a problem from occurring. Also, the first recess 34 and the second recess 36 are formed in separate steps, and thus, it is possible to individually control the thickness T1 (i.e., the depth of the first recess 34) and the thickness T2 (i.e., the depth of the second recess 36).

(1-6) The nitride semiconductor device 10 is configured as a HEMT using GaN. As a result, it is possible to provide the nitride semiconductor device having the advantages of (1-1) to (1-5) described above as a power device using a GaN-HEMT.

### Embodiment 2

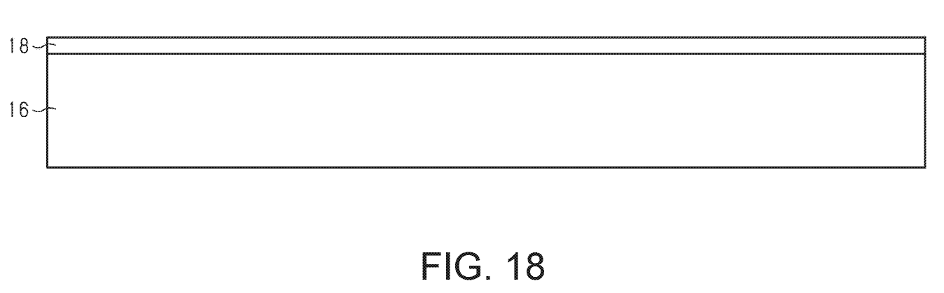

Next, a nitride semiconductor device 10 according to Embodiment 2 will be described below with reference to FIGS. 18-26. In Embodiment 2, some of the manufacturing steps in the manufacturing method for the nitride semiconductor device 10 differ from those of Embodiment 1, and the components of the nitride semiconductor device 10 are the same as those of Embodiment 1. Below, components similar to those of Embodiment1 are assigned the same reference characters and description thereof will be omitted; components differing from those of Embodiment 1 will be described.

As shown in FIG. 18, the manufacturing method for the nitride semiconductor device 10 according to Embodiment 2 includes forming the buffer layer 14 (see FIG. 1), the electron transport layer 16, and the electron supply layer 18 in the stated order over the semiconductor substrate 12 (see FIG. 1), which is an Si substrate, for example. The buffer layer 14, the electron transport layer 16, and the electron supply layer 18 can be subjected to epitaxial growth by MOCVD. The electron transport layer 16 is a GaN layer and the electron supply layer 18 is an AlGaN layer, for example.

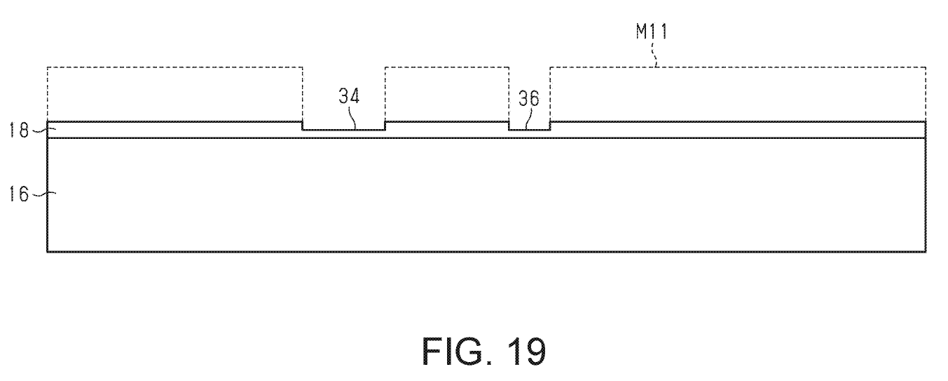

Next, in the manufacturing step shown in FIG. 19, a mask M11 formed over the electron supply layer 18 is used to etch a portion of the electron supply layer 18 to a given depth, thereby forming the first recess 34 and the second recess 36. Then, the mask M11 is removed. At this time, the etching depth is determined such that the thickness of the electron supply layer 18 in the first recess 34 is a target thickness based on the design of the gate threshold. The thickness of the electron supply layer 18 in the second recess 36 is the same as the thickness of the electron supply layer 18 in the first recess 34. Thus, the first recess 34 and the second recess 36 are formed simultaneously.

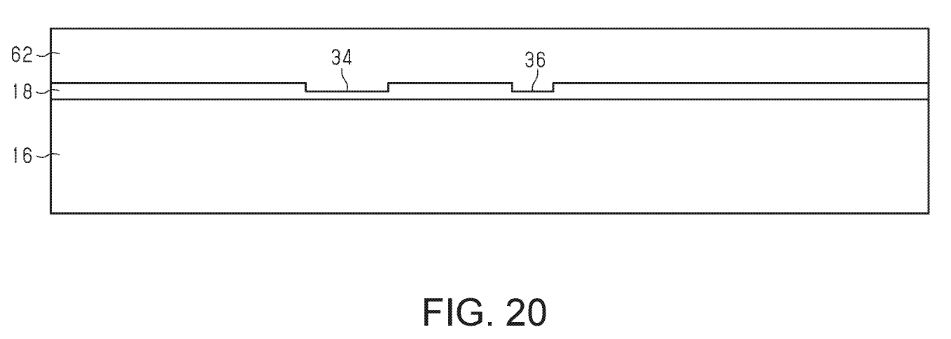

Next, in the manufacturing step shown in FIG. 20, a nitride semiconductor layer 62 is formed over the electron supply layer 18. The nitride semiconductor layer 62 is for forming the gate layer 22 described with reference to FIG. 1, and is formed by epitaxial growth by MOCVD. The nitride semiconductor layer 62 is a p-type GaN layer, for example. By regrowing the nitride semiconductor layer 62 over the electron supply layer 18, the nitride semiconductor layer 62 fills the first recess 34 and the second recess 36.

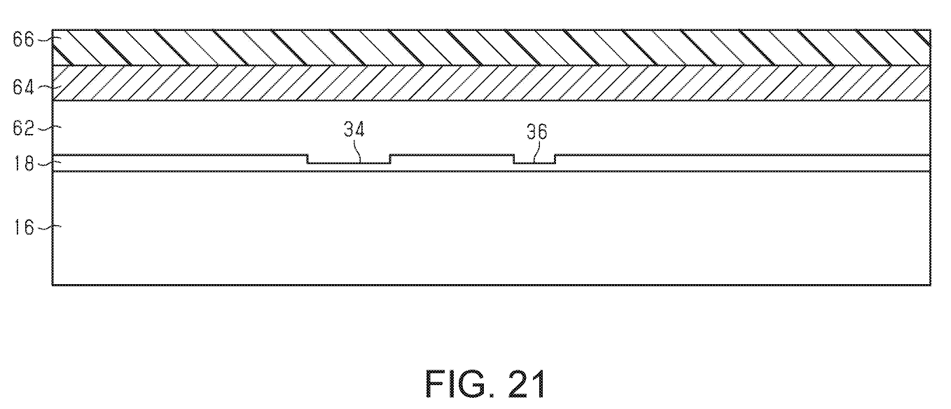

Next, in the manufacturing step shown in FIG. 21, an electrode layer 64 and a protective layer 66 are sequentially formed over the nitride semiconductor layer 62. The electrode layer 64 is for forming the gate electrode 24 described with reference to FIG. 1, and is formed by sputtering, for example. In one example, the electrode layer 64 is a TiN layer. The protective layer 66 is, for example, formed by PECVD, and in one example is an SiN layer.

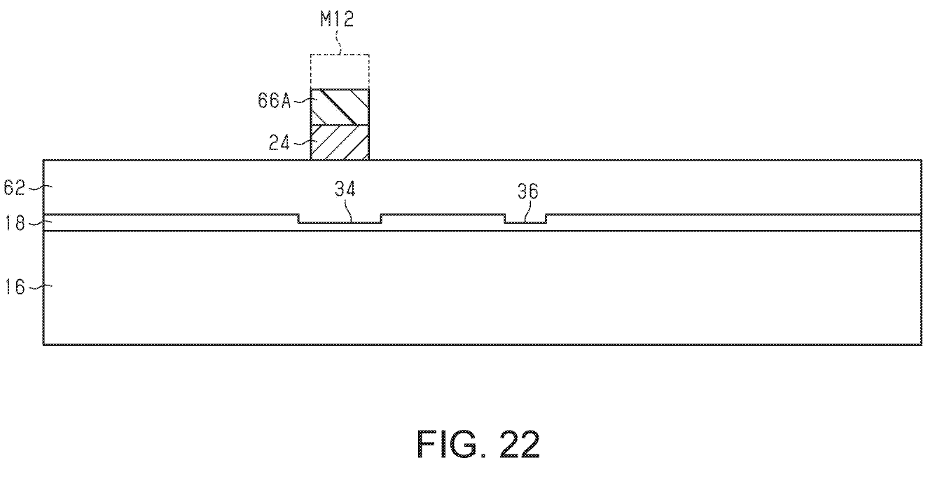

Next, in the manufacturing step shown in FIG. 22, the electrode layer 64 and the protective layer 66 are selectively removed by lithography and etching. In this step, a mask M12 is formed over the portion of the protective layer 66 corresponding to the region in which the gate electrode 24 is formed, and portions of the electrode layer 64 and the protective layer 66 not covered by the mask M12 are selectively removed. As a result, a protective section 66A is left remaining directly below the mask M12, and the gate electrode 24 is formed directly below the protective section 66A. Then, the mask M12 is removed.

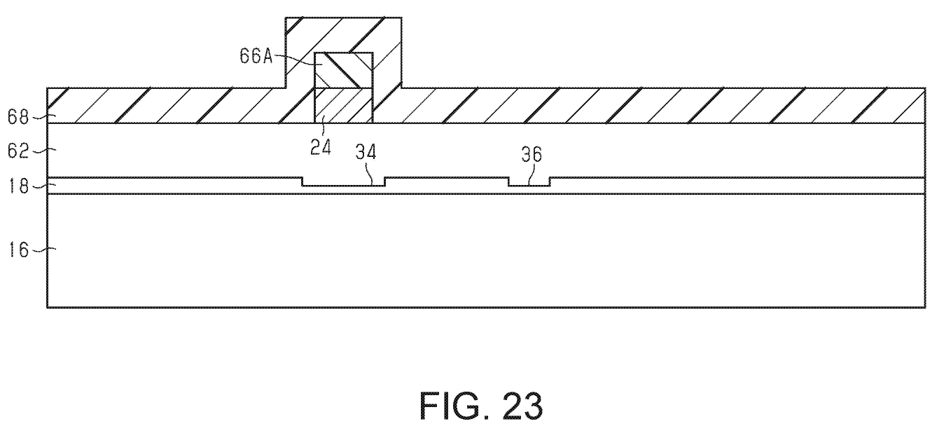

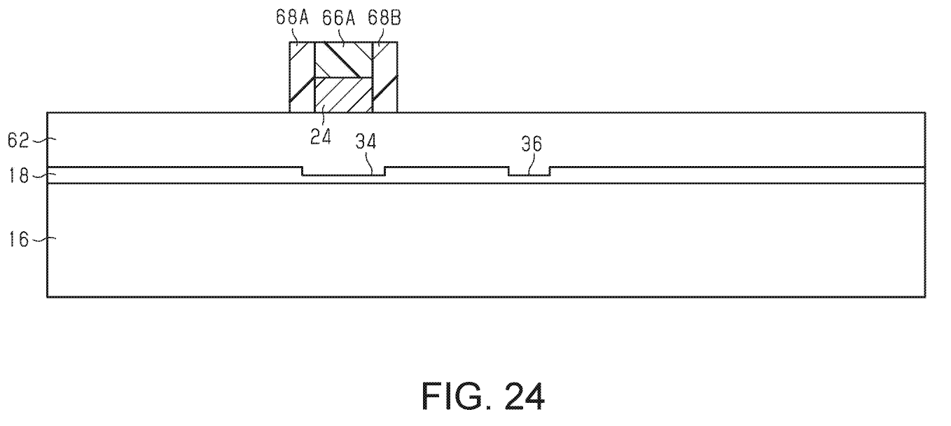

Next, in the manufacturing step shown in FIG. 23, a protective layer 68 covering the gate electrode 24 and the protective section 66A is formed over the nitride semiconductor layer 62. The protective layer 68 is, for example, formed by PECVD, and in one example is an SiN layer. Next, in the manufacturing step shown in FIG. 24, the protective layer 68 is etched back until the top surface of the nitride semiconductor layer 62 is exposed. As a result of the protective layer 68 being etched back, protective walls 68A and 68B covering the side walls of both the gate electrode 24 and the protective section 66A are formed.

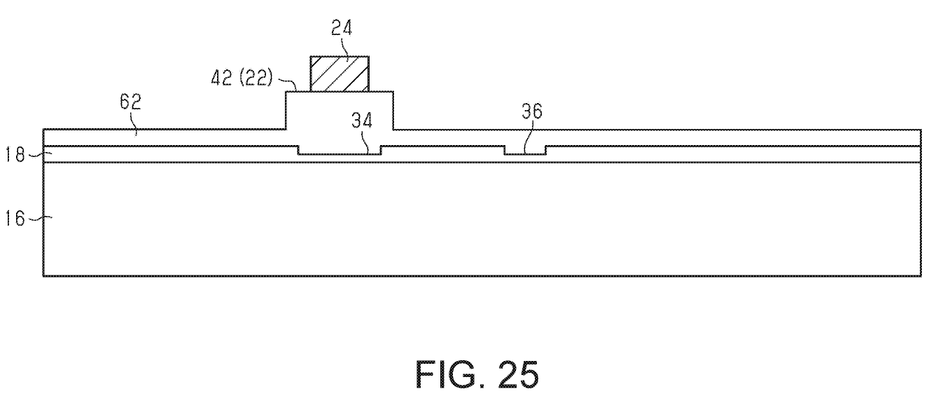

In the manufacturing step shown in FIG. 25, by etching (e.g., dry etching) the nitride semiconductor layer 62 to a given depth using the above-mentioned protective section 66A and the protective walls 68A and 68B as masks, the gate layer main body section 42 of the gate layer 22 is formed. In this step, a thinned portion of the nitride semiconductor layer 62 having a thickness corresponding to the source-side extending section 44 and the drain-side extending section 46 described with reference to FIG. 1 is left remaining on both sides of the gate layer main body section 42. Then, the protective section 66A and the protective walls 68A and 68B are removed.

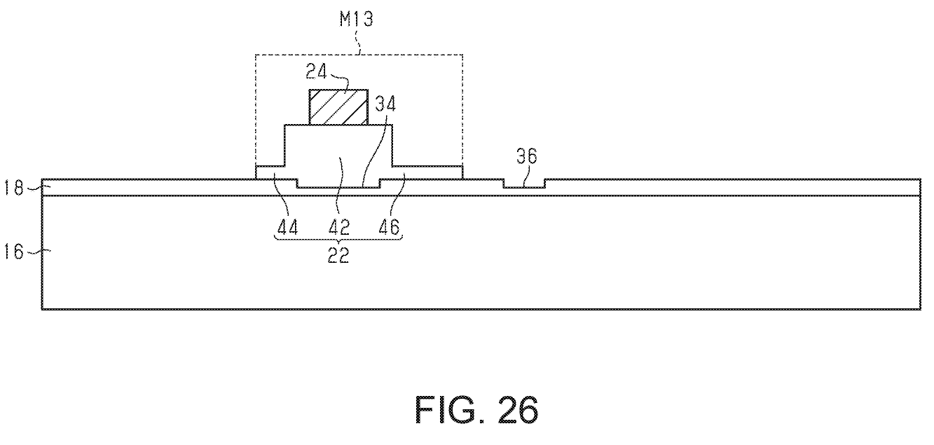

Next, in the manufacturing step shown in FIG. 26, by selectively etching the thinned portions of the nitride semiconductor layer 62 (see FIG. 25) using a mask M13 that covers the gate electrode 24 and the gate layer main body section 42, the source-side extending section 44 and the drain-side extending section 46 are formed. Then, the mask M13 is removed.

Then, by performing similar manufacturing steps to those described in Embodiment 1 with reference to FIGS. 14-17, the passivation layer 26, the source electrode 30, and the drain electrode 32 are formed. By the above manufacturing steps, the nitride semiconductor device 10 shown in FIG. 1 can be manufactured.

The nitride semiconductor device 10 of Embodiment 2 has the following advantages in addition to the advantages (1-1) to (1-3) and (1-6) of Embodiment 1.

(2-1) The first recess 34 and the second recess 36 are formed in the same step. Thus, the overall number of manufacturing steps is reduced and therefore the cost is lowered compared to Embodiment 1.

### Embodiment 3

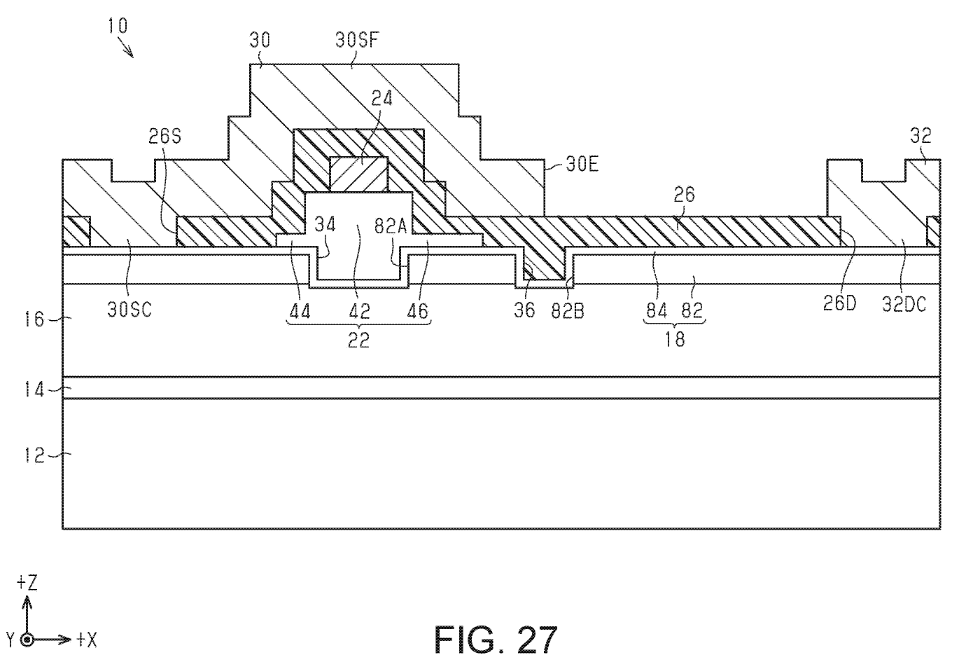

Next, a nitride semiconductor device 10 according to Embodiment 3 will be described below with reference to FIG. 27. In Embodiment 3, the configuration of the electron supply layer 18 differs from that of Embodiment 1. Below, components similar to those of Embodiment 1 are assigned the same reference characters and description thereof will be omitted; components differing from those of Embodiment 1 will be described.

As shown in FIG. 27, the electron supply layer 18 includes a first layer 82 (first nitride semiconductor layer) and a second layer 84 (second nitride semiconductor layer). The first layer 82 and the second layer 84 are constituted of the same nitride semiconductor, for example. In one example, the first layer 82 and the second layer 84 are AlGaN. Alternatively, the first layer 82 and the second layer 84 may be constituted of different nitride semiconductors.

The first layer 82 is positioned over the electron transport layer 16. The first layer 82 includes a first penetrating hole 82A and a second penetrating hole 82B that penetrate the first layer 82. The first and second penetrating holes 82A and 82B are formed by etching, for example. When forming the first and second penetrating holes 82A and 82B, portions of the top surface of the electron transport layer 16 exposed through the first and second penetrating holes 82A and 82B can also be etched.

The second layer 84 covers the top surface of the first layer 82 and the inner surfaces (bottom surfaces and side surfaces) of the first and second penetrating holes 82A and 82B. The second layer 84 is formed by regrowth of the nitride semiconductor layer (here, the AlGaN, for example) after the first and second penetrating holes 82A and 82B are formed. As a result, the top surface of the electron transport layer 16, which defines the bottom surfaces of the first and second penetrating holes 82A and 82B, the side walls of the first layer 82, which define the side surfaces of the first and second penetrating holes 82A and 82B, and the top surface of the first layer 82 are covered by the second layer 84. As a result, the first recess 34 is defined by the portion of the second layer 84 covering the inner surface of the first penetrating hole 82A, and the second recess 36 is defined by the portion of the second layer 84 covering the inner surface of the second penetrating hole 82B. In this configuration, by controlling the thickness of the second layer 84 to be regrown on the bottom of the first and second penetrating holes 82A and 82B, the thickness of the electron supply layer 18 in the first and second penetrating holes 34 and 36 can be determined.

The nitride semiconductor device 10 of Embodiment 3 has the following advantages in addition to the advantages (1-1) to (1-3) and (1-6) of Embodiment 1.

(3-1) The thickness of the electron supply layer 18 in the first and second penetrating holes 34 and 36 can be controlled by the second layer 84 to be regrown on the bottom of the first and second penetrating holes 82A and 82B. As a result, compared to a case in which the thickness of the electron supply layer 18 at the first and second recesses 34 and 36 is determined by etching, it is possible to more accurately control the thickness of the electron supply layer 18 at the first and second recesses 34 and 36.

### Modification Examples

The embodiments above can be modified as described below, for example. The embodiments and the modification examples below can be combined with each other as long as such a combination is technically compatible. In the modification examples below, components in common with the embodiments are assigned the same reference characters as the embodiments, and descriptions thereof are omitted.

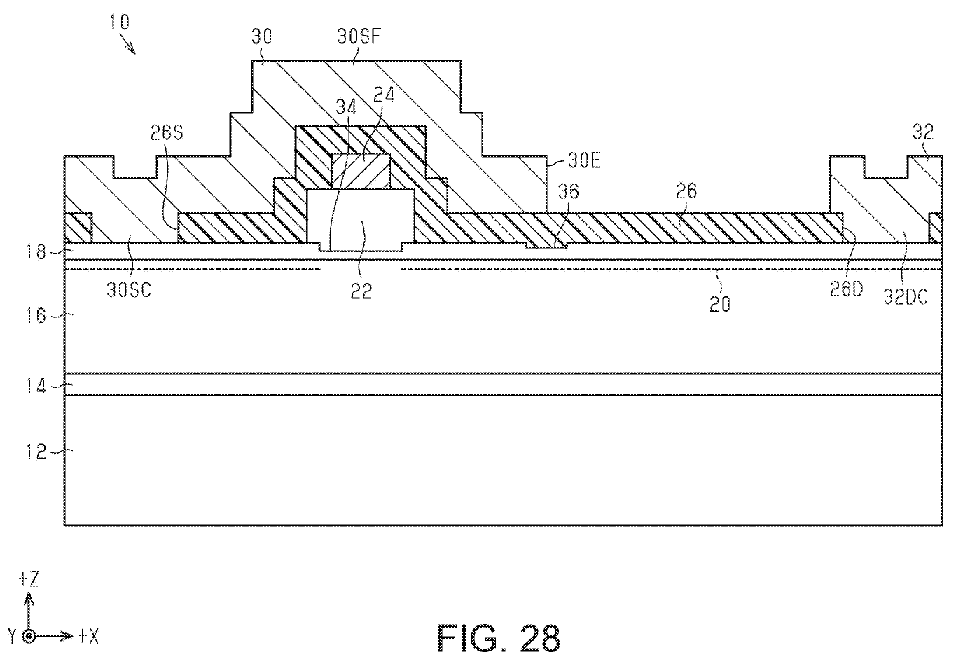

FIG. 28 is a schematic cross-sectional view of the nitride semiconductor device 10 according to a modification example. As shown in FIG. 28, the gate layer 22 need not have a stepped structure. In this modification example, the gate layer 22 includes only the portion corresponding to the gate layer main body section 42 of FIG. 1 (main body section length LG of FIG. 2) In this manner, the first recess 34 and the second recess 36 can be similarly applied to the nitride semiconductor device 10 that includes the gate layer 22 that does not have a stepped structure. In the modification example as well, the first recess 34 can have a length in the first direction X set to be less than that of the gate layer 22 in the first direction X. As a result, it is possible to mitigate a decrease in gate threshold by providing the first recess 34 while attaining the desired gate withstand voltage (GS withstand voltage) by maintaining the thickness of the electron supply layer 18 in the gate leakage current path (i.e., the thickness of the electron supply layer 18 directly below the source-side end section of the gate layer 22).

The first recess length L1 (length of the first recess 34) is not limited to being less than the main body section length LG (length of the gate layer main body section 42), and may be greater than or equal to the main body section length LG. However, from the perspective of mitigating an increase in ON resistance while maintaining the sheet carrier density of the 2DEG 20 as described above, it is preferable that the first recess length L1 be less than the main body section length LG.

The source electrode 30 is not limited to a configuration in which the field plate section 30SF is integral and continuous with the source contact section 30SC. As long as the field plate section 30SF is electrically connected to the source potential, the field plate section 30SF may be a separate unit from the source electrode 30.

The nitride semiconductor device 10 is not limited to an HEMT using the GaN, and may be a different type of nitride semiconductor transistor.

Language used in the present disclosure such as “over” can include both meanings of “on” or “above” as long as the context does not eliminate each of those possibilities. Thus, the expression “the first layer is formed over the second layer” is intended to allow for a given embodiment in which the first layer is directly disposed on the second layer in contact therewith, and another embodiment in which the first layer is disposed above the second layer without being in contact therewith. That is, the term “over” does not eliminate a structure in which another element is formed between the first layer and the second layer.

The Z direction used in the present disclosure need not necessarily indicate the vertical direction, and need not completely match the vertical direction. Thus, in the various structures of this disclosure, “up” and “down” in the Z direction described in the present specification are not limited to signifying “up” and “down” in the vertical direction. The X axis direction or the Y axis direction may be the vertical direction, for example.

### Notes

The technical concepts that can be ascertained from the present disclosure will be described below. The constituent elements disclosed in the notes below include the reference characters of the corresponding constituent elements of the embodiments in order to aid understanding, rather than to limit the invention. The reference characters indicate examples to aid understanding, and the constituent elements disclosed in the notes should not be understood as being limited to the constituent elements indicated by the reference characters.

### Note 1

A nitride semiconductor device (10), including:

an electron transport layer (16);

an electron supply layer (18) that is positioned over the electron transport layer (16) and has a bandgap greater than the electron transport layer (16);

a gate layer (22) positioned over a portion of the electron supply layer (18), and including an acceptor impurity;

a gate electrode (24) positioned over a portion of the gate layer (22);

a passivation layer (26) that covers the electron supply layer (18), the gate layer (22), and the gate electrode (24), and that includes a source opening (26S) and a drain opening (26D);

a source electrode (30) in contact with the electron supply layer (18) via the source opening (26S); and

a drain electrode (32) in contact with the electron supply layer (18) via the drain opening (26D),

wherein the source electrode (30) includes a field plate section (30SF) that covers the gate layer (22) and the gate electrode (24), and the field plate section (30SF) includes a field plate end section (30E) that is positioned between the gate layer (22) and the drain electrode (32), and

wherein the electron supply layer (18) includes:

a first recess (34) that is formed in a top surface of the electron supply layer (18), and that overlaps the gate layer (22) in a plan view; and

a second recess (36) that is formed in the top surface of the electron supply layer (18), and that overlaps the field plate end section (30E), in a plan view.

### Note 2

The nitride semiconductor device (10) according to Note 1,

wherein the gate layer (22) is positioned between the source opening (26S) and the drain opening (26D) along a first direction (X) in a plan view,

wherein the gate layer (22) has a gate layer length (LG) in the first direction (X), and

wherein the first recess (34) has a first recess length (L1) that is less than the gate layer length (LG) in the first direction (X).

### Note 3

The nitride semiconductor device (10) according to Note 2,

wherein the second recess (36) has a second recess length (L2) less than the first recess length (L1) in the first direction (X).

### Note 4

The nitride semiconductor device (10) according to Note 1,

wherein the electron supply layer (18) has a first thickness (T1) in the first recess (34), and a second thickness (T2) differing from the first thickness (T1) in the second recess (36).

### Note 5

The nitride semiconductor device (10) according to Note 4,

wherein the first thickness (T1) is less than the second thickness (T2).

### Note 6

The nitride semiconductor device (10) according to Note 1,

wherein the electron supply layer (18) has a first thickness (T1) in the first recess (34), and a second thickness (T2) that is the same as the first thickness (T1) in the second recess (36).

### Note 7

The nitride semiconductor device (10) according to any one of Notes 1 to 6,

wherein the gate layer (22) includes:

a gate layer main body section (42);

a source-side extending section (44) that extends from the gate layer main body section (42) to the source opening (26S); and

a drain-side extending section (46) that extends from the gate layer main body section (42) to the drain opening (26D), and

wherein the first recess (34) overlaps the gate layer main body section (42) in a plan view.

### Note 8

The nitride semiconductor device (10) according to Note 7,

wherein the gate layer main body section (42) is positioned between the source opening (26S) and the drain opening (26D) along a first direction (X) in a plan view,

wherein the gate layer main body section (42) has a main body section length (LG) in the first direction (X), and

wherein the first recess (34) has a first recess length (L1) that is less than the main body section length (LG) in the first direction (X).

### Note 9

The nitride semiconductor device (10) according to Note 8,

wherein the second recess (36) has a second recess length (L2) less than the first recess length (L1) in the first direction (X).

### Note 10

The nitride semiconductor device (10) according to Note 7,

wherein a thickness (T3) of the source-side extending section (44) and a thickness (T4) of the drain-side extending section (46) are greater than a first thickness (T1) of the electron supply layer (18) in the first recess (34), and greater than a second thickness (T2) of the electron supply layer (18) in the second recess (36).

### Note 11

The nitride semiconductor device (10) according to any one of Notes 1 to 3 and 6,

wherein the electron supply layer (18) includes:

a first nitride semiconductor layer (82) that is positioned over the electron transport layer (16), and that includes a first penetrating hole (82A) and a second penetrating hole (82B); and

a second nitride semiconductor layer (84) that covers a top surface of the first nitride semiconductor layer (82), an inner surface of the first penetrating hole (82A), and an inner surface of the second penetrating hole (82B),

wherein the first recess (34) is defined by a portion of the second nitride semiconductor layer (84) covering the inner surface of the first penetrating hole (82A), and

wherein the second recess (36) is defined by a portion of the second nitride semiconductor layer (84) covering the inner surface of the second penetrating hole (82B).

### Note 12

A manufacturing method for a nitride semiconductor device (10), including:

forming an electron transport layer (16);

forming an electron supply layer (18) having a bandgap greater than the electron transport layer (16) over the electron transport layer (16);

forming a gate layer (22) including an acceptor impurity over a portion of the electron supply layer (18);

forming a gate electrode (24) over a portion of the gate layer (22);

forming a source electrode (30) in contact with the electron supply layer (18); and

forming a drain electrode (32) in contact with the electron supply layer (18),

wherein the source electrode (30) includes a field plate section (30SF) that covers the gate layer (22) and the gate electrode (24),

wherein forming the electron supply layer (18) includes:

forming a first recess (34) in a top surface of the electron supply layer (18); and

forming a second recess (36) in a top surface of the electron supply layer (18),

wherein forming the gate layer (22) includes forming the gate layer (22) such that the first recess (34) overlaps the gate layer (22) in a plan view, and

wherein forming the source electrode (30) includes forming the source electrode (30) such that the second recess (36) overlaps a field plate end section (30E) of the field plate section (30SF) in a plan view.

### Note 13

The manufacturing method for a nitride semiconductor device (10) according to Note 12,

wherein the first recess (34) is formed in the top surface of the electron supply layer (18) before the gate layer (22) is formed, and

wherein the second recess (36) is formed in the top surface of the electron supply layer (18) after forming the gate layer (22).

### Note 14

The manufacturing method for a nitride semiconductor device (10) according to Note 12,

wherein the first recess (34) and the second recess (36) are formed simultaneously.

What is claimed is:

1. A nitride semiconductor device, comprising:
an electron transport layer;
an electron supply layer that is positioned over the electron transport layer and has a bandgap greater than a bandgap of the electron transport layer;
a gate layer positioned over a portion of the electron supply layer, and including an acceptor impurity;
a gate electrode positioned over a portion of the gate layer;
a passivation layer that covers the electron supply layer, the gate layer, and the gate electrode, and that includes a source opening and a drain opening;
a source electrode in contact with the electron supply layer via the source opening; and
a drain electrode in contact with the electron supply layer via the drain opening,
wherein the source electrode includes a field plate section that covers the gate layer and the gate electrode, and the field plate section includes a field plate end section that is positioned between the gate layer and the drain electrode, and
wherein the electron supply layer includes:
a first recess that is formed in a top surface of the electron supply layer, and that overlaps the gate layer in a plan view; and
a second recess that is formed in the top surface of the electron supply layer, and that overlaps the field plate end section in a plan view.

2. The nitride semiconductor device according to claim 1,
wherein the gate layer is positioned between the source opening and the drain opening along a first direction in a plan view,
wherein the gate layer has a gate layer length in the first direction, and
wherein the first recess has a first recess length that is less than the gate layer length in the first direction.

3. The nitride semiconductor device according to claim 2,
wherein the second recess has a second recess length less than the first recess length in the first direction.

4. The nitride semiconductor device according to claim 1,
wherein the electron supply layer has a first thickness in the first recess, and a second thickness differing from the first thickness in the second recess.

5. The nitride semiconductor device according to claim 4,
wherein the first thickness is less than the second thickness.

6. The nitride semiconductor device according to claim 1,
wherein the electron supply layer has a first thickness in the first recess, and a second thickness in the second recess that is the same as the first thickness.

7. The nitride semiconductor device according to claim 1,
wherein the gate layer includes:
a gate layer main body section;
a source-side extending section that extends from the gate layer main body section toward the source opening; and
a drain-side extending section that extends from the gate layer main body section toward the drain opening, and
wherein the first recess overlaps the gate layer main body section in a plan view.

8. The nitride semiconductor device according to claim 7,
wherein the gate layer main body section is positioned between the source opening and the drain opening along a first direction in a plan view,
wherein the gate layer main body section has a main body section length in the first direction, and
wherein the first recess has a first recess length that is less than the main body section length in the first direction.

9. The nitride semiconductor device according to claim 8,
wherein the second recess has a second recess length less than the first recess length in the first direction.

10. The nitride semiconductor device according to claim 7,
wherein a thickness of the source-side extending section and a thickness of the drain-side extending section are greater than a first thickness of the electron supply layer in the first recess, and greater than a second thickness of the electron supply layer in the second recess.

11. The nitride semiconductor device according to claim 1,
wherein the electron supply layer includes:
a first nitride semiconductor layer that is positioned over the electron transport layer, and that includes a first penetrating hole and a second penetrating hole; and
a second nitride semiconductor layer that covers a top surface of the first nitride semiconductor layer, an inner surface of the first penetrating hole, and an inner surface of the second penetrating hole,
wherein the first recess is defined by a portion of the second nitride semiconductor layer covering the inner surface of the first penetrating hole, and
wherein the second recess is defined by a portion of the second nitride semiconductor layer covering the inner surface of the second penetrating hole.
